(19) United States
(12) Patent Application Publication
(10) Pub. No.: US 2021/0057467 A1
(43) Pub. Date: Feb. 25, 2021

(54) Backside Illumination Image Sensor

(71) Applicant: Huaian Imaging Device Manufacturer Corporation, Huaian (CN)

(72) Inventors: He WAN, Huaian (CN); Guiqin FANG, Huaian (CN); Rende HUANG, Huaian (CN)

(21) Appl. No.: 16/099,655

(22) PCT Filed: Jun. 21, 2018
(86) PCT No.: PCT/CN2018/092100

§ 371 Date: Nov. 7, 2018

(30) Foreign Application Priority Data
Nov. 7, 2017 (CN) 201711084283.2

(51) Int. Cl. H01L 27/146

(52) U.S. Cl. CPC H01L 27/1464; H01L 27/14636; H01L 27/14645; H01L 27/14627

(57) ABSTRACT

A backside illumination image sensor includes an outer photosensitive region and an inner photosensitive region; a first microlens array disposed on the outer photosensitive region and a second microlens array disposed on the inner photosensitive region; an electroluminescent film array arranged on the inner microlens array but not on the outer microlens array; and a signal processing and voltage conversion circuit array connects to the electroluminescent film and the metal interconnection structures in one-to-one correspondence; wherein the outer photosensitive region converts optical signals from the first microlens array to an excitation electrical signal, and the inner photosensitive region converts optical signals excited by the electroluminescent film array and passed from the second microlens array into an image output signal. The electroluminescent film array emits blue light, red light, and green light under electrical signals generated by the signal processing and voltage conversion circuit.

### CROSS REFERENCES TO RELATED APPLICATIONS

This application is the US National Stage Entry based on PCT Application No. PCT/CN2018/092100 filed on Jun. 21, 2018, which claims the benefit of priority to Chinese Patent Application No. CN201711084283.2, entitled “Backside Illumination Image Sensor”, filed with SIPO on Nov. 7, 2017, the contents of which are incorporated herein by reference in its entirety.

### TECHNICAL FIELD

The present disclosure relates to the technical field of semiconductors, and in particular, to a backside illumination image sensor.

### BACKGROUND

Backside illumination (BSI) image sensors have been widely applied to various technology fields. The structure of an existing backside illumination image sensor is shown in FIG. 1. The existing backside illumination image sensor mainly includes: a metal interconnection layer 10, a plurality of photosensitive regions 11 distributed at intervals on an upper surface of the metal interconnection layer 10, color filters 12 located on upper surfaces of the photosensitive regions 11, and microlenses 13 located on the color filters 12. In the existing backside illumination image sensor, incident light focused by the microlenses 13 is converted to specific color light, for example, red, green or blue, by the specific color filters 12, each of the filtered color light is passed to the photosensitive region 11 and converted to an electrical signal, which is then output via a proper route in the metal interconnection layer 10.

In the backside illumination image sensor shown in FIG. 1, a photosensitive diode (not shown) is disposed in the photosensitive region 11, and incident light is converted to an electrical signal through the photosensitive diode. However, when image is not bright enough to overcome noise, signal to noise ratio can be a problem, thereby an output image becomes blurred. The present disclosure intends to solve the image blurring problem in the current backside illumination image sensors.

### SUMMARY

The present disclosure provides a backside illumination image sensor, including: a substrate; a metal interconnection layer arranged in a top surface of the substrate; a photosensitive device layer on the metal interconnecting layer, comprising a first photosensitive region and a second photosensitive region electrically isolated from each other; a first microlens array disposed on the first photosensitive region and a second microlens array disposed on the second photosensitive region.

An electroluminescent film array arranged on the second microlens array but not on the first microlens array; and a signal processing and voltage conversion circuit array is configured to connect to the electroluminescent film array and the metal interconnection structures in one-to-one correspondence. The first photosensitive region converts a received first optical signal from the first microlens array to an excitation electrical signal, and the second photosensitive region converts a received second optical signal excited by the electroluminescent film array and passed from the second microlens array into an image output signal; wherein the metal interconnection layer comprises a plurality of metal interconnection structures electrically connecting to the first and second photosensitive regions in an one-to-one correspondence, and processing the image output signal.

The electroluminescent film array emits optical signals comprising blue light, red light and green light under electrical signals generated by the signal processing and voltage conversion circuit.

Optionally, the first microlens is located on the periphery of the second microlens.

Optionally, the area of the first microlens is greater than or equal to 0.9 μm².

Optionally, the first photosensitive region comprises a first photosensitive diode, the first photosensitive diode being electrically connected to the metal interconnection structure and configured to convert a received external optical signal to an excitation electrical signal and output the excitation electrical signal via the metal interconnection structure; and the second photosensitive region comprises a second photosensitive diode, the second photosensitive diode being electrically connected to the metal interconnection structure and configured to convert a received optical signal excited by the electroluminescent film array to an image output signal and output the image output signal via the metal interconnection structure.

Optionally, the electroluminescent film comprises a first electroluminescent film, a second electroluminescent film and a third electroluminescent film, wherein under the excitation of the excitation electrical signal amplified by the signal processing and voltage conversion circuit, the first electroluminescent film emits blue light, the second electroluminescent film emits red light, and the third electroluminescent film emits green light.

Optionally, the metal interconnection structure, the photosensitive region, the microlens component and the electroluminescent film, stacked up and down, jointly form an image sub-pixel, four adjacent image sub-pixels arranged in an array forming a pixel; and four electroluminescent films in each pixel comprise two third electroluminescent films, one first electroluminescent film and one second electroluminescent film.

Optionally, the electroluminescent film the electroluminescent film array comprises a positive electrode layer, a luminescent film layer and a negative electrode layer, wherein the positive electrode layer is located between the second microlens and the luminescent film layer, and extends to at least one side surface of the second microlens; and wherein the negative electrode layer covers a portion of a upper surface of the luminescent film layer.

Optionally, the positive electrode layer comprises an indium tin oxide layer.

Optionally, the backside illumination image sensor further comprises a first connection wire and a second connection wire, wherein one end of the first connection wire is electrically connected to the metal interconnection structure, and the other end is electrically connected to the negative electrode layer; and one end of the second connection wire is electrically connected to the metal interconnection structure, and the other end is electrically connected to the positive electrode layer and the signal processing and voltage conversion circuit. Optionally, the backside illumination image sensor further comprising an isolation layer, wherein the isolation layer is located between two adjacent first and second photosensitive regions, between the first connection wire and the first photosensitive region, between the first connection wire and the second photosensitive region, between the first connection wire and the first microlens, between the first connection wire and the second microlens, between the positive electrode layer and the luminescent film layer, and between the second connection wire and the second photosensitive region, and between the positive electrode layer and the luminescent film layer.

Optionally, the signal processing and voltage conversion circuit comprises a 4T APS pixel circuit and an amplification circuit, wherein the 4T APS pixel circuit is electrically connected to the metal interconnection structure via the second connection wire; and the amplification circuit is electrically connected to the 4T APS pixel circuit, the positive electrode layer and the negative electrode layer.

### BRIEF DESCRIPTION OF THE DRAWINGS

FIG. 1 shows a cross sectional view of a structure diagram of a current backside illumination image sensor.

FIG. 2 shows a cross sectional view of a structure diagram of a backside illumination image sensor according to an embodiment of the present disclosure.

FIG. 3 shows a top view diagram of a pixel in a backside illumination image sensor according to an embodiment of the present disclosure.

FIG. 4 shows a cross sectional view of a schematic structure diagram of an image sub-pixel in a backside illumination image sensor according to another embodiment of the present disclosure.

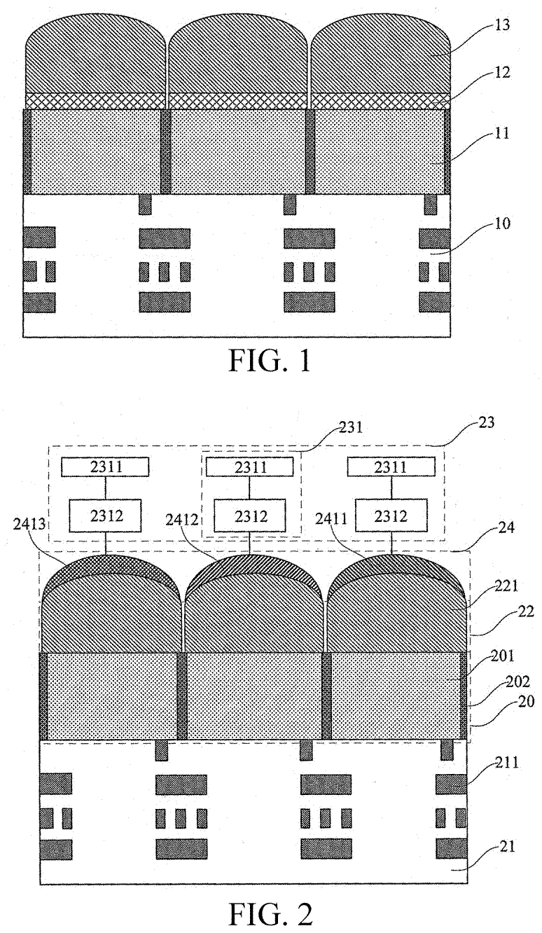

### DESCRIPTION OF REFERENCE NUMBERS

10 Metal interconnection layer
11 Photosensitive region
12 Color filter
13 Microlens
20 Photosensitive device layer
201 Photosensitive region
2011 First photosensitive region
2012 Second photosensitive region
202 Isolation structure
21 Metal interconnection layer
211 Metal interconnection structure
22 Microlens array
221 Microlens component
2211 First microlens
2212 Second microlens
23 Signal processing and voltage conversion circuit array
231 Signal processing and voltage conversion circuit
2311 4T APS pixel circuit
2312 Amplification circuit
24 Electroluminescent film array
241 Electroluminescent film
2411 First electroluminescent film
2412 Second electroluminescent film
2413 Third electroluminescent film
2414 Positive electrode layer
2415 Luminescent film layer
2416 Negative electrode layer
25 First connection wire
26 Second connection wire
27 Insulated isolation layer
3 Image sub-pixel
4 Pixel

### DETAILED DESCRIPTION OF THE PREFERRED EMBODIMENTS

The foregoing objectives, features and advantages of the present disclosure will become more apparent from the following detailed description of specific embodiments of the disclosure in conjunction with the accompanying drawings. In the detailed description of the embodiments of the present disclosure, for convenience of description, the schematic diagram will be partially enlarged not according to an ordinary ratio, and the schematic diagram is only an example, which should not limit the protection scope of the present disclosure. In addition, three-dimensional space dimensions of length, width and depth should be comprised in actual production.

The implementation manners of the present disclosure will be described below with reference to specific examples. Those skilled in the art may easily understand other advantages and effects of the present disclosure by the contents disclosed in the present specification. The present disclosure may also be implemented or applied through other different specific implementation manners. Various modifications or changes may also be made on the details in the present specification without departing from the spirit of the present disclosure based on different viewpoints and applications.

Please refer to FIG. 2 to FIG. 4. It should be noted that the illustration provided in the present embodiment merely illustrates the basic concept of the present disclosure by way of illustration. Although only components related to the present disclosure are shown in the illustration, they are not drawn according to the number, shape and size of the components in actual implementation. The form, quantity and proportion of various components in actual implementation may be a random change, and the layout of the components may also be more complex.

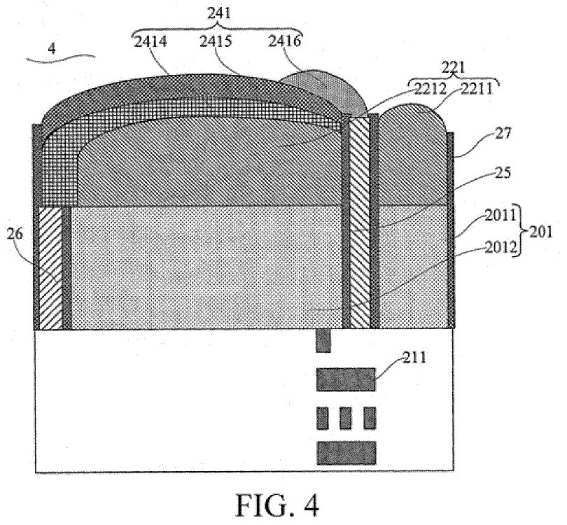

As shown in FIG. 2 to FIG. 4, the present disclosure provides an embodiment of a backside illumination image sensor. The backside illumination image sensor includes a photosensitive device layer 20, a metal interconnection layer 21, a microlens array 22, a signal processing and voltage conversion circuit array 23, and an electroluminescent film array 24, here the photosensitive device layer 20 comprises a plurality of photosensitive regions 201 distributed at intervals in an array, two adjacent photosensitive regions 201 are isolated by an isolation structure 202. As shown in FIG. 4, the photosensitive region 201 comprises a first photosensitive region 2011 and a second photosensitive region 2012 isolated from each other, the first photosensitive region 2011 is configured to convert a received external optical signal to an excitation electrical signal, and the second photosensitive region 2012 is configured to convert a received optical signal which is excited by the electroluminescent film array 24 to an image output signal. The metal interconnection layer 21 is located on a lower surface of the photosensitive device layer 20, the metal interconnection layer 21 comprises a plurality of metal interconnection structures 211, each of 211 is located under one of the photosensitive regions 201 in an one-to-one correspondence, and each metal interconnection structure 211 is electrically connected to the corresponding photosensitive region 201. The photoelectric signal is converted from the corresponding photosensitive region 201 and is configured into an image output signal. The microlens array 22 comprises a plurality of microlens components 221, each of the components 221 is placed above one of the photosensitive regions 201 in an one-to-one correspondence.

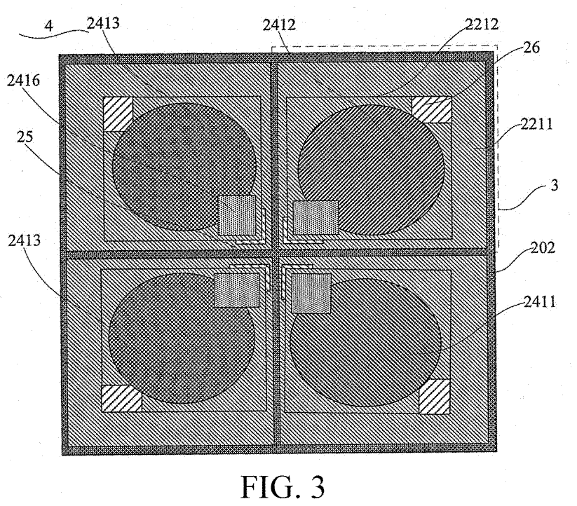

FIG. 4 shows the cross sectional view of one of the four image sensors disclosed in a top view in FIG. 3. One of the four of image sensors, sensor 3, contains one microlens responsible for the signal under the electroluminescent film 2415 and a side microlens outside the electroluminescence film designed to eliminate noise. As shown in FIG. 4, the microlens component 221 comprises a first microlens 2211 and a full sized second microlens 2212. The first microlens 2211 is located on the upper surface of the first photosensitive region 2011 and configured to focus external optical signals within its optical view to the first photosensitive region 2011, and the second microlens 2212 is located on the upper surface of the second photosensitive region 2012 and configured to focus optical signals excited by the electroluminescent film array 24 to the second photosensitive region 2012; the signal processing and voltage conversion circuit array 23 comprises a plurality of signal processing and voltage conversion circuits 231 connected with the metal interconnection structures 211M one-to-one correspondence, the signal processing and voltage conversion circuit is configured to amplify an excitation electrical signal output by the metal interconnection structure 211 correspondingly connected thereto. The electroluminescent film array 24 comprises a plurality of electroluminescent films 241, the electroluminescent film 241 is located on an upper surface of the second microlens 2212, electrically connected to the signal processing and voltage conversion circuit 231 and configured to emit an optical signal comprising blue light, red light and green light under the excitation of the excitation electrical signal amplified by the signal processing and voltage conversion circuit 231.

As an example, as shown in FIG. 4, the first photosensitive region 2011 comprises a first photosensitive diode (not shown), the first photosensitive diode is electrically connected to the metal interconnection structure 211 and configured to convert a received external optical signal to an excitation electrical signal and output the excitation electrical signal via the metal interconnection structure 211; and the second photosensitive region 2012 comprises a second photosensitive diode (not shown), the second photosensitive diode is electrically connected to the metal interconnection structure 211 and configured to convert a received optical signal excited by the electroluminescent film array 24 to an image output signal and output the image output signal via the metal interconnection structure 211.

It should be noted that the metal interconnection layer 21 may further comprise a dielectric layer (not marked), the metal interconnection structures 211 are located in the dielectric layer, and each metal interconnection structure 211 is insulated and isolated by the dielectric layer.

As an example, referring to FIG. 3 and FIG. 4, the first microlens 2211 is located on the periphery of the second microlens 2212, and the area of the first microlens 2211 may be set according to actual noise reduction requirements. Preferably, in the present embodiment, the area of the first microlens 2211 should be greater than or equal to 0.9 μm², such that the first microlens 2211 can focus sufficient external optical signals to be converted to corresponding excitation electrical signals. Of course, in other examples, the area of the first microlens 2211 may also be any other values according to actual requirements.

As an example, referring to FIG. 2 and FIG. 4, the electroluminescent film 241 comprises a first electroluminescent film 2411, a second electroluminescent film 2412 and a third electroluminescent film 2413, wherein under the excitation of the excitation electrical signal amplified by the signal processing and voltage conversion circuit 231, the first electroluminescent film 2411 emits blue light, the second electroluminescent film 2412 emits red light, and the third electroluminescent film 2413 emits green light.

As an example, the electroluminescent film 241 may be made of an organic electroluminescent material or an inorganic electroluminescent material. For example, the first electroluminescent film 2411 may be made of, but not limited to, PVK (polyvinyl carbazole), and the second electroluminescent film 2412 and the third electroluminescent film 2413 may be made of, but not limited to, a ZnS-based doped material.

As an example, as shown in FIG. 3, the metal interconnection structure 211, the photosensitive region 201, the microlens component 221 and the electroluminescent film 241, which are stacked up and down, jointly form an image sub-pixel 3, four adjacent image sub-pixels 3 arranged in an array form a pixel 4; and four electroluminescent films 241 in each pixel 4 comprise two third electroluminescent films 2413, one first electroluminescent film 2411 and one second electroluminescent film 2412. The second microlenses 2212 of the four image sub-pixels 3 in one pixel 4 are coated with the first electroluminescent film 2411, the second electroluminescent film 2412 and the third electroluminescent film 2413 respectively. Corresponding blue light, red light and green light are emitted under the excitation of an electrical signal amplified by the signal processing and voltage conversion circuit 231, the emitted light is configured to be sensed and received by the second photosensitive region 2012, so that color filters in the existing backside illumination image sensor can be omitted.

It should be noted that one pixel 4 comprises two third electroluminescent films 2413, one first electroluminescent film 2411 and one second electroluminescent film 2412, wherein coating positions of the first electroluminescent film 2411, the second electroluminescent film 2412 and the third electroluminescent films 2413 may be set according to actual requirements. For example, as shown in FIG. 3, the two third electroluminescent films 2413 may be coated on the two second microlenses 2212 in the same left column, and the first electroluminescent film 2411 and the second electroluminescent film 2412 may be coated on the two second microlenses 2212 in the same right column respectively. Alternatively, the two third electroluminescent films 2413 may be coated on the two second microlenses 2212 at a left upper corner and a right lower corner in the pixel 4, and the first electroluminescent film 2411 and the second electroluminescent film 2412 may be coated on the two second microlenses 2212 at a left lower corner and a right upper corner in the pixel 4 respectively. In addition, there are also many other coating manners, which will not be enumerated here.

As an example, referring to FIG. 4, the electroluminescent film 241 comprises a positive electrode layer 2414, a luminescent film layer 2415 and a negative electrode layer 2416, wherein the positive electrode layer 2414 is located on an upper surface of the second microlens 2212, and extends from the upper surface of the second microlens 2212 to at least one side surface of the second microlens 2212; the luminescent film layer 2415 is located on an upper surface of the positive electrode layer 2414; and the negative electrode layer 2416 is located on an upper surface of the luminescent film layer 2415 and covers part of the luminescent film layer 2415. That is, the first electroluminescent film 2411, the second electroluminescent film 2412 and the third electroluminescent film 2413 all comprise the positive electrode layer 2414, the luminescent film layer 2415 and the negative electrode layer 2416 mentioned above. Their difference lies in that the luminescent film layers 2415 in different electroluminescent films 241 are made of different materials, such that different colors of light may be emitted.

As an example, the positive electrode layer 2414 may comprise, but is not limited to, an indium tin oxide (ITO) layer. The negative electrode layer 2416 may be any one conductive material layer, and the negative electrode layer 2416 may be evaporated on an upper surface of the luminescent film layer 2415 by using a process such as evaporation. It should be noted that the negative electrode layer 2416 only covers part of the upper surface of the luminescent film layer 2415.

As an example, the backside illumination image sensor further comprises a first connection wire 25 and a second connection wire 26, wherein one end of the first connection wire 25 is electrically connected to the metal interconnection structure 211, and the other end is electrically connected to the negative electrode layer 2416; and one end of the second connection wire 26 is electrically connected to the metal interconnection structure 211, and the other end is electrically connected to the positive electrode layer 2414 and the signal processing and voltage conversion circuit 231.

As an example, the backside illumination image sensor further comprises an insulated isolation layer 27, the insulated isolation layer 27 is located between two adjacent photosensitive regions 201, between the first connection wire 25 and the first photosensitive region 2011, between the first connection wire 25 and the second photosensitive region 2012, between the first connection wire 25 and the first microlens 2211, between the first connection wire 25 and the second microlens 2212, between the first connection wire 25 and the positive electrode layer 2414, between the first connection wire 25 and the luminescent film layer 2415, between the second connection wire 26 and the first photosensitive region 2011, between the second connection wire 26 and the positive electrode layer 2414, and between the second connection wire 26 and the luminescent film layer, so as to electrically isolate the adjacent photosensitive regions 201, and electrically isolate the first connection wire 25 and the second connection wire 26 from other structures adjacent thereto.

As an example, please refer to FIG. 2 again, the signal processing and voltage conversion circuit 231 comprises a 4T APS pixel circuit 2311 and an amplification circuit 2312, wherein the 4T APS pixel circuit 2311 is electrically connected to the metal interconnection structure 211 via the second connection wire 26; and the amplification circuit 2312 is electrically connected to the 4T APS pixel circuit 2311, the positive electrode layer 2414 and the negative electrode layer 2416. A specific structure of the 4T APS pixel circuit 2311 is known to those skilled in the art, and will not be repeated here. The amplification circuit 2312 may be any one of the existing amplification circuits. A specific structure thereof will not be repeated here.

Referring to FIG. 2 and FIG. 4, the electroluminescent film 241 is provided on the second microlens 2212 and it is externally connected to the signal processing and voltage conversion circuit 231 which is capable of amplifying an optical signal to the electroluminescent film 241, the backside illumination image sensor provided in the present disclosure may output a clear image under the condition of low image signal light, such that the image sensor may be normally used in a dark environment with weak light, thereby greatly expanding the application range of the backside illumination image sensor.

The working principle of the backside illumination image sensor according to the present disclosure is that: the first microlens with its surface not coated with the electroluminescent film 241 focuses external optical signals to the first photosensitive region 2011, the first photosensitive region 2011 senses light and converts the received external optical signal to an excitation electrical signal; and the excitation electrical signal is transmitted to the signal processing and voltage conversion circuit 231 via the metal interconnection structure 211 and the second connection wire and scaled up, and the amplified electrical signal is transmitted to each electroluminescent film 241 as an illumination voltage of the electroluminescent film 241. Since the amplification circuit 2312 may scale up the excitation electrical signal converted by the first photosensitive region 2011, the electroluminescent film 241 will emit different colors of optical signals with different illuminations under the excitation of the amplified electrical signal, the optical signal excited by the electroluminescent film 241 is sensed by the second photosensitive region 2012, and the second photosensitive region 2012 excites electrons to output a very clear pattern.

In a summary, the present disclosure provides a backside illumination image sensor. The backside illumination image sensor at least comprises a photosensitive device layer, a metal interconnection layer, a microlens array, a signal processing and voltage conversion circuit array, and an electroluminescent film array, wherein the photosensitive device layer internally comprises a plurality of photosensitive regions distributed at intervals in an array; the photosensitive region comprises a first photosensitive region and a second photosensitive region isolated from each other, the first photosensitive region being configured to convert a received external optical signal to an excitation electrical optical signal, and the second photosensitive region being configured to convert a received optical signal excited by the electroluminescent film array to an image output signal; the metal interconnection layer is located on a lower surface of the photosensitive device layer, the metal interconnection layer internally comprises a plurality of metal interconnection structures in one-to-one up-down correspondence to the photosensitive regions, and each metal interconnection structure is electrically connected to the corresponding photosensitive region and is configured to output an excitation electrical signal converted by the corresponding photosensitive region and an image output signal; the microlens array comprises a plurality of microlens components in one-to-one up-down correspondence to the photosensitive regions; the microlens component comprises a first microlens and a second microlens, the first microlens being located on an upper surface of the first photosensitive region and configured to focus an external optical signal to the first photosensitive region, and the second microlens being located on an upper surface of the second photosensitive region and configured to focus an optical signal excited by the electroluminescent film array to the second photosensitive region; the signal processing and voltage conversion circuit array comprises a plurality of signal processing and voltage conversion circuits in one-to-one correspondence connection with the metal interconnection structures, each signal processing and voltage conversion circuit being configured to amplify an excitation electrical signal output by the metal interconnection structure correspondingly connected thereto; and the electroluminescent film array comprises a plurality of electroluminescent films, the electroluminescent film being located on an upper surface of the second microlens, electrically connected to the signal processing and voltage conversion circuit and configured to emit an optical signal comprising blue light, red light and green light under the excitation of the excitation electrical signal amplified by the signal processing and voltage conversion circuit.

The technical solution of the present disclosure has the following advantages:

by disposing an electroluminescent film on a microlens and externally connecting a signal processing and voltage conversion circuit which is capable of amplifying an optical signal to the electroluminescent film, the backside illumination image sensor according to the present disclosure may output a clear image under the condition of very weak light, such that the image sensor may be normally used in a weak-light dark environment, thereby greatly expanding the usage range of the backside illumination image sensor. Meanwhile, a color filter is not required for the backside illumination image sensor according to the present disclosure.

The above embodiments merely illustrate the principle and effects of the present disclosure, but are not to limit the present disclosure. Any person skilled in the art can modify or vary the above embodiments without departing from the spirit and scope of the present disclosure. Accordingly, all equivalent modifications or variations completed by those with ordinary skill in the art without departing from the spirit and technical thought disclosed in the present disclosure should still be covered by the claims of the present disclosure.

1. A backside illumination image sensor, comprising:
a substrate;
a metal interconnection layer arranged in a top surface of the substrate;
a photosensitive device layer on the metal interconnecting layer, comprising a first photosensitive region and a second photosensitive region electrically isolated from each other;
a first microlens array disposed on the first photosensitive region and a second microlens array disposed on the second photosensitive region;
an electroluminescent film array arranged on the second microlens array but not on the first microlens array; and
a signal processing and voltage conversion circuit array configured to connect to the electroluminescent film and the metal interconnection structures in one-to-one correspondence;
wherein the first photosensitive region converts a received first optical signal from the first microlens array to an excitation electrical signal, and the second photosensitive region converts a received second optical signal excited by the electroluminescent film array and passed from the second microlens array into an image output signal; wherein the metal interconnection layer comprises a plurality of metal interconnection structures electrically connecting to the first and second photosensitive regions in an one-to-one correspondence, and processing the image output signal; and
wherein the electroluminescent film array emits optical signals comprising blue light, red light and green light under electrical signals generated by the signal processing and voltage conversion circuit.

2. The backside illumination image sensor according to claim 1, wherein the first microlens is located on the periphery of the second microlens.

3. The backside illumination image sensor according to claim 2, wherein the area of the first microlens is greater than or equal to 0.9 μm².

4. The backside illumination image sensor according to claim 1, wherein the first photosensitive region comprises a first photosensitive diode, wherein the first photosensitive diode is electrically connected to the metal interconnection structure and configured to convert the first optical signal to an excitation electrical signal and output the excitation electrical signal via the metal interconnection structure; and wherein the second photosensitive region comprises a second photosensitive diode, wherein the second photosensitive diode is electrically connected to the metal interconnection structure and configured to convert the second optical signal excited by the electroluminescent film array to an image output signal and output the image output signal via the metal interconnection structure.

5. The backside illumination image sensor according to claim 1, wherein the electroluminescent film array comprises a first electroluminescent film, a second electroluminescent film and a third electroluminescent film, wherein under the excitation of the excitation electrical signal amplified by the signal processing and voltage conversion circuit, the first electroluminescent film emits blue light, the second electroluminescent film emits red light, and the third electroluminescent film emits green light.

6. The backside illumination image sensor according to claim 5, wherein the metal interconnection structure, the first and second photosensitive regions, the first and second microlens arrays and the electroluminescent film stacked up, forming an image sub-pixel, four of the adjacent image sub-pixel are arranged in a pixel; and wherein the electroluminescent film array in each pixel comprises two third electroluminescent films, one first electroluminescent film, and one second electroluminescent film.

7. The backside illumination image sensor according to claim 1, wherein the electroluminescent film array comprises a positive electrode layer, a luminescent film layer and a negative electrode layer, wherein the positive electrode layer is located between the second microlens and the luminescent film layer, and, and extends to at least one side surface of the second microlens; and wherein the negative electrode layer covers a portion of a upper surface of the luminescent film layer.

8. The backside illumination image sensor according to claim 7, wherein the positive electrode layer comprises an indium tin oxide layer.

9. The backside illumination image sensor according to claim 7, further comprising a first connection wire and a second connection wire, wherein the first connection wire is electrically connected to the metal interconnection structure at one end, and to the negative electrode layer at another end; and the second connection wire is electrically connected to the metal interconnection structure at one end, and to the positive electrode layer and the signal processing and voltage conversion circuit at another end.

10. The backside illumination image sensor according to claim 9, further comprising an isolation layer, wherein the isolation layer is located between two adjacent first and second photosensitive regions, between the first connection wire and the first photosensitive region, between the first connection wire and the second photosensitive region, between the first connection wire and the first microlens, between the first connection wire and the second microlens, between the positive electrode layer and the luminescent film layer, and between the second connection wire and the second photosensitive region, and between the positive electrode layer and the luminescent film layer.

11. The backside illumination image sensor according to claim 9, wherein the signal processing and voltage conversion circuit comprises a 4T APS pixel circuit and an amplification circuit, wherein the 4T APS pixel circuit is electrically connected to the metal interconnection structure via the second connection wire; and wherein the amplification circuit is electrically connected to the 4T APS pixel circuit, the positive electrode layer and the negative electrode layer.
